(19) United States
(12) Patent Application Publication
(10) Pub. No.: US 2025/0365973 A1
(43) Pub. Date: Nov. 27, 2025

(54) SEMICONDUCTOR MEMORY DEVICES AND METHODS OF MANUFACTURING THEREOF

(71) Applicant: Taiwan Semiconductor Manufacturing Company, Ltd., Hsinchu (TW)

(72) Inventors: Meng-Han Lin, Hsinchu City (TW); Chia-En Huang, Xinfeng Township (TW); Sai-Hooi Yeong, Zhubei City (TW)

(73) Assignee: Taiwan Semiconductor Manufacturing Company, Ltd., Hsinchu (TW)

(21) Appl. No.: 19/296,371

(22) Filed: Aug. 11, 2025

Related U.S. Application Data
(62) Division of application No. 17/835,769, filed on Jun. 8, 2022.

(51) Int. Cl. H10B 51/20; G11C 11/22; H10B 51/10

(52) U.S. Cl. CPC H10B 51/20; G11C 11/223; G11C 11/2253; G11C 11/2297; H10B 51/10

(57) ABSTRACT

A semiconductor device includes a memory structure comprising a plurality of first memory cells. The semiconductor device includes a test structure disposed next to the memory structure and comprising a first monitor pattern. The plurality of first memory cells, arranged along a first lateral direction, that have a plurality of first channel films extending along a vertical direction, respectively, and share a first ferroelectric film extending along the vertical direction and the first lateral direction. The first monitor pattern includes: (a) a second channel film extending along the vertical direction and the first lateral direction; and (b) a second ferroelectric film extending along the vertical direction and the first lateral direction.

### CROSS-REFERENCE TO RELATED APPLICATIONS

The present application is a divisional of U.S. patent application Ser. No. 17/835,769, filed on Jun. 8, 2022, the entire disclosure of which is incorporated herein by reference for all purposes.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a block diagram of a memory system and a host, in accordance with some embodiments.

FIG. 1B illustrates a block diagram of a memory core control circuit, in accordance with some embodiments.

FIG. 1C illustrates a block diagram of a memory core, in accordance with some embodiments.

FIG. 1D illustrates a block diagram of a memory bank, in accordance with some embodiments.

FIG. 1E illustrates a block diagram of a memory block, in accordance with some embodiments.

FIG. 2 illustrates a perspective view of an example memory block and its corresponding test structure, in accordance with some embodiments.

FIG. 3 illustrates an example polarization-voltage curve associated with a ferroelectric film of the memory block/test structure of the memory block of FIG. 2, in accordance with some embodiments.

FIG. 4 is an example flow chart of a method for fabricating a memory device, in accordance with some embodiments.

FIGS. 5A, 5B, 6A, 6B, 7A, 7B, 8A, 8B, 9A, 9B, 10A, 10B, 11A, 11B, 12A, 12B, 13A, and 13B illustrate perspective views of an example memory device during various fabrication stages, made by the method of FIG. 4, in accordance with some embodiments.

FIGS. 14A and 14B illustrate top views of the example memory device shown in FIGS. 5A-13B, during one of the fabrication stages, in accordance with some embodiments.

FIGS. 15A and 15B illustrate a prospective view and a top view of the example memory device shown in FIGS. 5A-13B, during one of the fabrication stages, in accordance with some embodiments.

FIGS. 16A and 16B illustrate a prospective view and a top view of the example memory device shown in FIGS. 5A-13B, during one of the fabrication stages, in accordance with some embodiments.

FIGS. 17A and 17B illustrate a prospective view and a top view of the example memory device shown in FIGS. 5A-13B, during one of the fabrication stages, in accordance with some embodiments.

FIG. 18 illustrates a cross-sectional view of the example memory device shown in FIGS. 5A-13B, during one of the fabrication stages, in accordance with some embodiments.

FIG. 19 illustrates a top view of the example memory device shown in FIGS. 5A-13B, during one of the fabrication stages, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A ferroelectric material refers to a material that displays spontaneous polarization of electrical charges in the absence of an applied electric field. The net polarization P of electrical charges within the ferroelectric material is non-zero in the minimum energy state. Thus, spontaneous ferroelectric polarization of the material occurs, and the ferroelectric material accumulates surfaces charges of opposite polarity types on two opposing surfaces. Polarization P of a ferroelectric material as a function of an applied voltage V thereacross displays hysteresis. The product of the remanant polarization and the coercive field of a ferroelectric material is a metric for characterizing effectiveness of the ferroelectric material.

A ferroelectric memory device is a memory device containing the ferroelectric material which is used to store information. The ferroelectric material acts as the memory material of the memory device. The dipole moment of the ferroelectric material is programmed in two different orientations (e.g., “up” or “down” polarization positions based on atom positions, such as oxygen and/or metal atom positions, in the crystal lattice) depending on the polarity of the applied electric field to the ferroelectric material to store information in the ferroelectric material. The different orientations of the dipole moment of the ferroelectric material may be detected by the electric field generated by the dipole moment of the ferroelectric material.

A non-volatile memory device retains data stored therein even when not powered. Two-dimensional non-volatile memory devices in which memory cells are fabricated in a single layer over a substrate have reached physical limits in terms of increasing their degree of integration. In this regard, three-dimensional (3D) non-volatile memory devices in which memory cells are stacked in a vertical direction over a substrate have been proposed. In general, a 3D non-volatile memory device includes at least some of the features of its memory cells that extend beyond two dimensions. As such, the 3D memory device can allow its various memory cells to be vertically stacked over or integrated with one another.

The present disclosure provides various embodiments of a 3D memory device that utilizes a ferroelectric material as its memory material. In various embodiments, the 3D memory device can have a number of memory cells arranged as a 2D memory array. The memory cells of such a 2D memory array can have their word line (WL) structures, which function as respective gates, extending along both a vertical direction and a lateral direction, and their bit line (BL) structures, which function as respective drains, and source line (SL) structures, which function as respective sources, extending along the vertical direction. Further, the memory cells can have their ferroelectric films and channel films extending in parallel with the WL structures (e.g., extending along the vertical direction and lateral direction). As such, a number of such 2D memory arrays can be vertically stacked on top of one another to form a 3D memory device (or array).

By utilizing such a 3D structure, properties of the ferroelectric films of the memory cells can be more efficiently monitored, in various embodiments. For example, disposed next to the 2D memory array (sometimes referred to as a memory structure), a test structure, which is substantially similar to the memory structure except for the electrically isolated channel films, can be formed. The test structure can be concurrently formed with the memory structure, which allows the test structure to emulate various physical features (e.g., the WL structures, the ferroelectric films, the SL structures, the BL structures) formed within the memory structure. As a result, a polarization-voltage (PV) curve associated with the ferroelectric films formed within the memory structure can be accurately monitored based on a PV curve associated with the ferroelectric films formed within the test structure. Such a PV curve is sometimes referred to as a ferroelectric hysteresis curve or loop, which is generally used to determine various characteristics of a ferroelectric memory cell/device. For example, based on the monitored PV curve, any defect associated with the ferroelectric films formed within the memory structure (e.g., an insufficiently large PV window, etc.) can be quickly identified.

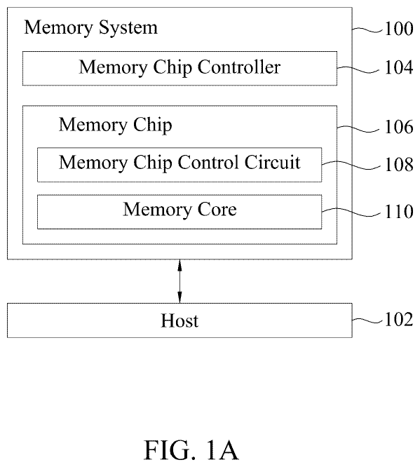

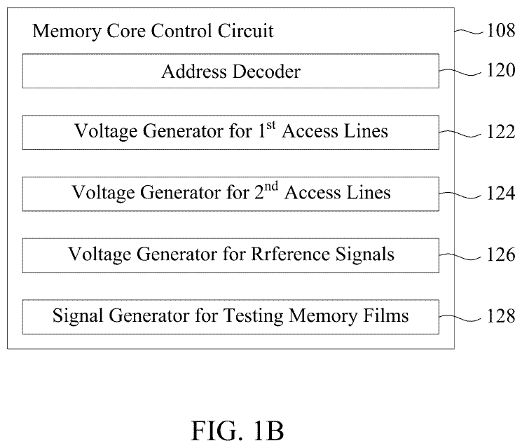

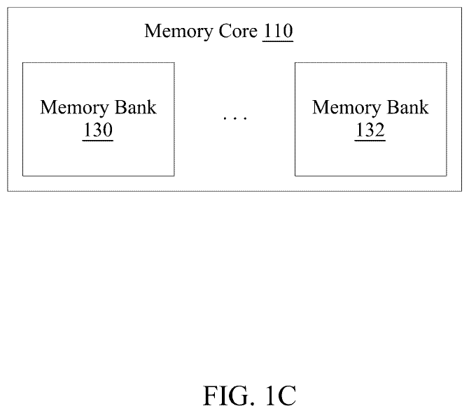

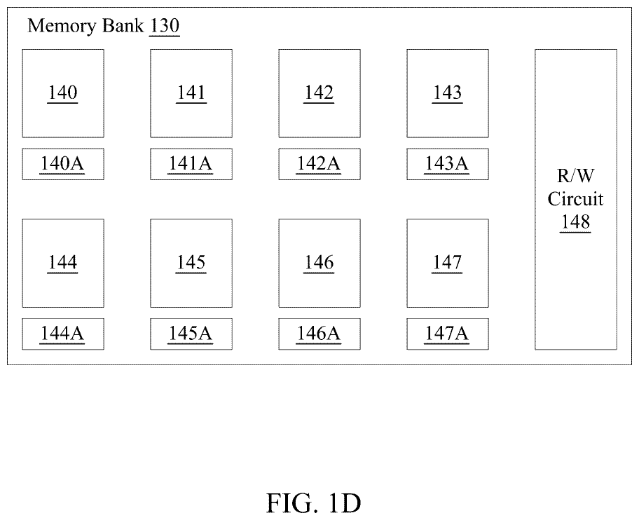

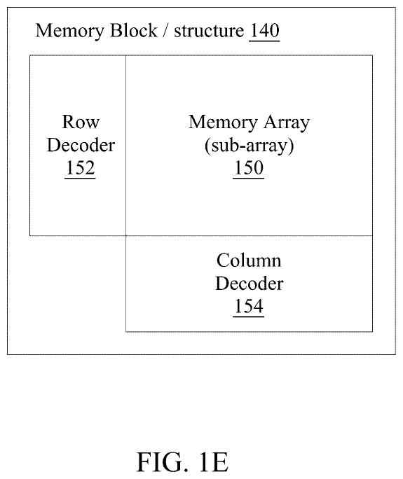

FIG. 1A illustrates a block diagram including a memory system 100 and a host 102, in accordance with various embodiments. The memory system 100 may include a non-volatile storage system interfacing with the host 102 (e.g., a mobile computing device). In some embodiments, the memory system 100 may be embedded within the host 102. In some embodiments, the memory system 100 may include a memory card. As shown, the memory system 100 includes a memory chip controller 104 and a memory chip 106. Although a single memory chip 106 is shown, the memory system 100 may include any number of memory chips (e.g., four, eight or some other number of memory chips), while remaining within the scope of the present disclosure. The memory chip controller 104 can receive data and commands from the host 102 and provide memory chip data to the host 102.

The memory chip controller 104 may include one or more state machines, page registers, SRAM, and control circuitry for controlling the operation of the memory chip 106. The one or more state machines, page registers, static random access memory (SRAM), and control circuitry for controlling the operation of the memory chip 106 may sometimes be referred to as managing or control circuits. The managing or control circuits may facilitate one or more memory array operations, such as forming, erasing, programming, and reading operations.

In some embodiments, the managing or control circuits (or a portion of the managing or control circuits) for facilitating one or more memory array operations may be integrated within the memory chip 106. The memory chip controller 104 and memory chip 106 may be arranged on a single integrated circuit. In other embodiments, the memory chip controller 104 and memory chip 106 may be arranged on different integrated circuits. In some cases, the memory chip controller 104 and memory chip 106 may be integrated on a system board, logic board, or a printed circuit board (PCB).

The memory chip 106 includes memory core control circuit 108 and a memory core 110. In various embodiments, the memory core control circuit 108 may include logic for controlling the selection of memory blocks (or arrays) within the memory core 110 such as, for example, controlling the generation of voltage references for biasing a particular memory array into a read or write state, generating row and column addresses, testing memory films (e.g., ferroelectric films) of the memory blocks, which will be discussed in further detail below.

The memory core 110 may include one or more two-dimensional arrays of non-volatile memory cells or one or more three-dimensional arrays of non-volatile memory cells. In an embodiment, the memory core control circuit 108 and memory core 110 are arranged on a single integrated circuit. In other embodiments, the memory core control circuit 108 (or a portion of the memory core control circuit 108) and memory core 110 may be arranged on different integrated circuits.

An example memory operation may be initiated when the host 102 sends instructions to the memory chip controller 104 indicating that the host 102 would like to read data from the memory system 100 or write data to the memory system 100. In the event of a write (or programming) operation, the host 102 will send to the memory chip controller 104 both a write command and the data to be written. The data to be written may be buffered by the memory chip controller 104 and error correcting code (ECC) data may be generated corresponding with the data to be written. The ECC data, which allows data errors that occur during transmission or storage to be detected and/or corrected, may be written to the memory core 110 or stored in non-volatile memory within the memory chip controller 104. In an embodiment, the ECC data are generated and data errors are corrected by circuitry within the memory chip controller 104.

The memory chip controller 104 can control operation of the memory chip 106. In one example, before issuing a write operation to the memory chip 106, the memory chip controller 104 may check a status register to make sure that the memory chip 106 is able to accept the data to be written. In another example, before issuing a read operation to the memory chip 106, the memory chip controller 104 may pre-read overhead information associated with the data to be read. The overhead information may include ECC data associated with the data to be read or a redirection pointer to a new memory location within the memory chip 106 in which to read the data requested. Once a read or write operation is initiated by the memory chip controller 104, the memory core control circuit 108 may generate the appropriate bias voltages for word lines and bit lines within memory core 110, and generate the appropriate memory block, row, and column addresses.

FIG. 1B illustrates one example block diagram of the memory core control circuit 108, in accordance with various embodiments. As shown, the memory core control circuit 108 include an address decoder 120, a voltage generator for first access lines 122, a voltage generator for second access lines 124, a signal generator for reference signals 126, and a signal generator for testing memory films 128 (described in more detail below). In some embodiments, access lines may include word line (WL) structures, bit line (BL) structures, source/select line (SL) structures, or combinations thereof. Further, first access lines may include selected WL structures, selected BL structures, and/or selected SL structures that are used to place non-volatile memory cells into a selected state; and second access lines may include unselected WL structures, unselected BL structures, and/or unselected SL structures that are used to place non-volatile memory cells into an unselected state.

In accordance with various embodiments, the address decoder 120 can generate memory block addresses, as well as row addresses and column addresses for a particular memory block. The voltage generator (or voltage regulators) for first access lines 122 can include one or more voltage generators for generating first (e.g., selected) access line voltages. The voltage generator for second access lines 124 can include one or more voltage generators for generating second (e.g., unselected) access line voltages. The signal generators for reference signals 126 can include one or more voltage and/or current generators for generating reference voltage and/or current signals. The signal generator for testing memory films 128 can generate a sweeping voltage (e.g., a voltage signal swept over a certain period of time) to be applied on a selected WL for testing the ferroelectric films of the memory blocks, which will be discussed in further detail below.

FIGS. 1C-1E illustrate an example organization of the memory core 110, in accordance with various embodiments. The memory core 110 includes a number of memory banks, and each memory bank includes a number of memory blocks. Although an example memory core organization is disclosed where memory banks each include memory blocks, and memory blocks each include a group of non-volatile memory cells (arranged as a memory array or sub-array), other organizations or groupings also can be used, while remaining within the scope of the present disclosure.

FIG. 1C illustrates an example block diagram of the memory core 110, in accordance with various embodiments. As shown, the memory core 110 includes memory banks 130, 132, etc. It should be appreciated the memory core 100 can include any number of memory banks, while remaining within the scope of the present disclosure. For example, a memory core may include only a single memory bank or multiple memory banks (e.g., 16 or other number of memory banks).

FIG. 1D illustrates an example block diagram of one of the memory banks (e.g., 130) shown in FIG. 1C, in accordance with various embodiments. As shown, the memory bank 130 includes memory blocks (or structures) 140, 141, 142, 143, 144, 145, 146, and 147, and test structures 140A, 141A, 142A, 143A, 144A, 145A, 146A, and 147A respectively corresponding to the memory blocks 140 to 147, and a read/write circuit 148. It should be appreciated the memory bank 130 can include any number of memory blocks/structures (and any according number of the test structures), while remaining within the scope of the present disclosure. For example, a memory bank may include one or more memory blocks (e.g., 32 or other number of memory blocks per memory bank). The read/write circuit 148 can include circuitry for reading and writing memory cells within the memory blocks 140 to 147. Further, although one test structures correspond to each memory block in the illustrated example of FIG. 1D (and the following figures), it should be appreciated that any number of test structures can correspond to one memory block, while remaining within the scope of the present disclosure.

In various embodiments, the test structures 140A through 147A, together with the corresponding memory blocks 140 through 147, may be formed on a single die (e.g., a singulated or cut die). Each test structure may be physically disposed next to its corresponding memory block. For example in FIG. 1D, the test structure 140A may be physically disposed along one side of the memory block 140. However, it should be understood that the test structure may be physically arranged next to the corresponding memory block in any of various other manners. In one aspect, the test structure may be disposed in an isolation region configured to electrically isolate one or more functional blocks that contain the corresponding memory block. In another aspect, the test structure may be disposed within a functional block and between one or more logic circuits (e.g., logic gates, inverters, ring oscillators, switches, etc.) contained in the functional block, which can also include the corresponding memory block.

In some other embodiments, the test structures may not be present on a single die (e.g., a singulated or cut die). For example, while the memory blocks of a memory core (e.g., 110) are formed on a particular die over a wafer, the corresponding test structures may be formed along scribe lines over the wafer. A scribe line (sometimes referred to as a kerf or frame) is an area in a wafer, which is used to singulate or otherwise separate individual dies at the end of wafer processing. In such embodiments, the test structures may not be present on a singulated die.

In some embodiments, the read/write circuit 148 may be shared across multiple memory blocks within a memory bank. This allows chip area to be reduced because a single group of read/write circuit 148 may be used to support multiple memory blocks. However, in some embodiments, only a single memory block may be electrically coupled to the read/write circuit 148 at a particular time to avoid signal conflicts. In some embodiments, the read/write circuit 148 may be used to write one or more pages of data into the memory blocks 140-147 (or into a subset of the memory blocks). The non-volatile memory cells within the memory blocks 140-147 may permit direct over-writing of pages (i.e., data representing a page or a portion of a page may be written into the memory blocks 140-147 without requiring an erase or reset operation to be performed on the non-volatile memory cells prior to writing the data).

In some cases, the read/write circuit 148 may be used to program a particular non-volatile memory cell to be in one of multiple (e.g., 2, 3, etc.) data states. For example, the particular non-volatile memory cell may include a single-level or multi-level non-volatile memory cell. In one example, the read/write circuits 148 may apply a first voltage difference (e.g., 2V) across the particular non-volatile memory cell to program the particular non-volatile memory cell into a first state of the multiple data states or a second voltage difference (e.g., 1V) across the particular non-volatile memory cell that is less than the first voltage difference to program the particular non-volatile memory cell into a second state of the multiple data states.

FIG. 1E illustrates an example block diagram of one of the memory blocks (e.g., 140) of the memory bank 130 of FIG. 1D, in accordance with various embodiments. As shown, the memory block 140 includes a memory array (or sometimes referred to as a memory sub-array) 150, a row decoder 152, and a column decoder 154. As disclosed herein, the memory array 150 may include a contiguous group of non-volatile memory cells, each of which can be accessed through a respective combination of access lines (e.g., a combination of one of contiguous WL structures, one of contiguous BL structures, and one of contiguous SL structures). Such access lines may sometimes be referred to as an interface portion of the memory block, in some embodiments. The memory array 150 may include one or more layers of non-volatile memory cells. The memory array 150 may include a two-dimensional memory array or a three-dimensional memory array. The interface portion may be formed within the memory array 150, which will be shown and discussed in further detail below.

The row decoder 152 can decode a row address and select a particular WL structure, when appropriate (e.g., when reading or writing non-volatile memory cells in the memory array 150). The column decoder 154 can decode a column address and select one or more BL structures/SL structures in the memory array 150 to be electrically coupled to read/write circuits, such as the read/write circuit 148 in FIG. 1D. As a non-limiting example, the number of WL structures is in the range of 4K per memory layer, the number of BL structures/SL structures is in the range of 1K per memory layer, and the number of memory layers is 4, which renders about 16M non-volatile memory cells contained in the memory array 150 (of the memory block 140). Continuing with the same example, a test structure (e.g., 140A), corresponding to the memory block 140, may include the similar number of WL structures (e.g., 4K) and the similar number of memory layers (e.g., 4), but a much less number of BL structures/SL structures (in some implementations), which can allow the test structures to occupy an optimized real estate.

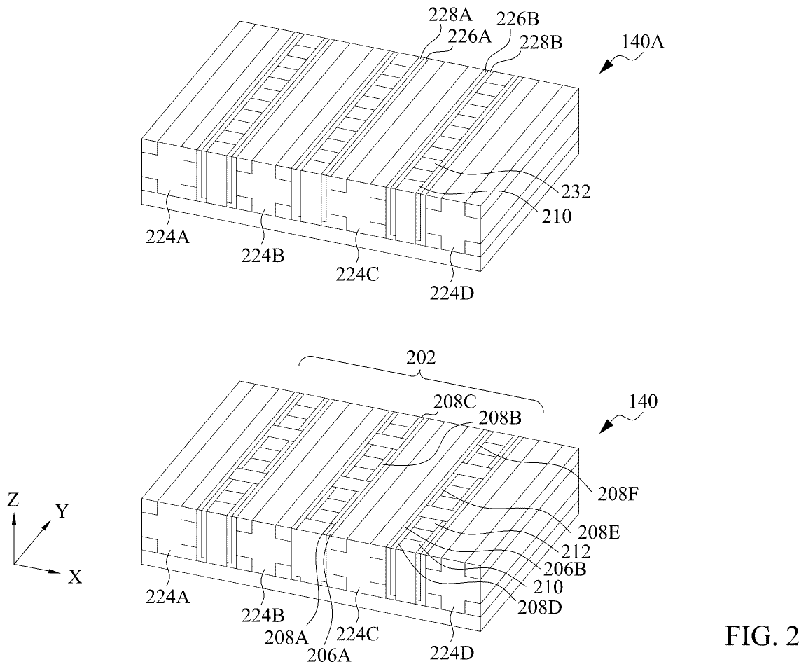

FIG. 2 illustrates a perspective view of a portion of the memory block (e.g., the memory array portion) and its corresponding test structure, according to various embodiments of the present disclosure. In the following discussions, the memory block 140 (and its corresponding test structure 140A) are selected as a representative example. It should be understood that other memory blocks (and corresponding test structures), as disclosed herein, are substantially similar to the memory block 140 (and the test structure 140A), and thus, the discussions are not repeated. Further, the perspective view of FIG. 2 is simplified, and thus, it should be understood that any of various other features/components can also be included in FIG. 2, while remaining within the scope of the present disclosure. For example, a number of interconnect structures formed over the memory block 140 for routing the BL structures and SL structures are not shown.

As shown, the memory block 140 includes an implementation of the memory array (or sub-array) 150, which is herein referred to as memory array 202. Such a memory array 202 shown in FIG. 2 includes a number of memory cells formed within one memory layer, e.g., forming a 2D memory array. It should be appreciated that any number of such memory layers can be stacked on top of one another (e.g., along the Z direction) to form a 3D memory array. Each of the memory cells can include a laterally extending WL structure functioning as a gate to control a vertically extending channel film through a vertically extending ferroelectric film (disposed on one side of the channel film), and the channel film, on the other side, is in electrical contact with a pair of vertically extending SL structure and BL structure, which will be discussed in further detail as follows.

For example, the memory array 202 includes a number of WL structures, 204A, 204B, 204C, and 204D, each of which extends along the Y direction. Further, the WL structures 204A-D can each have at least a portion of its cross-section present in a cross shape, e.g., having a horizontal portion extending across the X direction and Y direction and a vertical portion extending across the Z direction and Y direction. Such horizontal and vertical portions can traverse across each other. The memory array 202 further includes a number of ferroelectric films, e.g., 206A, 206B, etc., extending along the Y direction and the Z direction. As shown, each of the WL structures 204A-D can be in contact with two of such ferroelectric films through its corresponding horizontal portion. The memory array 202 further includes a number of channel films, e.g., 208A, 208B, 208C, 208D, 208E, 208F, etc., extending along the Y direction and the Z direction. As shown, each of the WL structures 204A-D can be electrically coupled to a number of such channel films through the two coupled ferroelectric films 206A and 206B. The channel films arranged on either side of the corresponding WL structure are physically and electrically isolated from each other, in some embodiments. The memory array 202 further includes a number of pairs of BL structures 210 and SL structures 212 that each extend along the Z direction. As shown, each of the channel films (e.g., 208D), on its opposite side coupled to the WL structure, is in contact with a corresponding pair of the BL structure 210 and SL structure 212.

The memory cell of the memory array 202 may be defined as a combination of one of the WL structures (e.g., 204), a portion of the ferroelectric films (e.g., 206A, 206B), one of the channel films (e.g., 208A-F), and one of the pairs of SL structure 212 and BL structure 210. Such a memory cell may be implemented as a transistor structure (sometimes referred to as a “one-transistor (1T) structure”) with a gate, a gate oxide/dielectric layer, a semiconductor channel, a source, and a drain. The WL structure, the ferroelectric film, the channel film, the BL structure, and the SL structure may function as a gate, a gate dielectric layer, a semiconductor channel, a drain, and a source of the memory cell, respectively.

In various embodiments, the test structure 140A and the memory block 140 may be concurrently formed. As such, the test structure 140A may be substantially similar to the memory block 140, except that its channel films may each be formed as a continuously integrated layer. For example, the test structure 140A also includes WL structures (e.g., 224A, 224B, 224C, 224D, etc.); ferroelectric films (e.g., 226A, 226B, etc.); channel films (e.g., 228A, 228B, etc.); BL structures (e.g., 230); and SL structures (e.g., 232). The WL structures 224A-D, ferroelectric films 226A-B, BL structures 230, and SL structures 232 can be substantially similar to the WL structures 204A-D, ferroelectric films 206A-B, BL structures 210, and SL structures 212, respectively, and thus, the discussion will not be repeated. Different from the memory block 140, the channel films 228A-B may continuously extend along the Y direction, without being segmented into discrete portions like the channel films 208A-F.

In various embodiments, the test structure 140A is configured to emulate various components of the memory block 140 (e.g., by forming them concurrently). As a non-limiting example, the WL structure 224A-D, or one or more selected ones of the WL structures 224A-D, can be applied with a sweeping voltage (e.g., through the signal generator for testing memory films 128 of FIG. 1B) with the BL structures 230 and SL structures 232 tied to ground. As such, a polarization-voltage (PV) curve of the ferroelectric films 226A-B can be derived. As the ferroelectric films 226A-B of the test structure 140A are concurrently formed with the ferroelectric films 206A-B of the memory block 140, a PV curve of the ferroelectric films 206A-B can be accurately monitored or otherwise emulated by the PV curve of the ferroelectric films 226A-B.

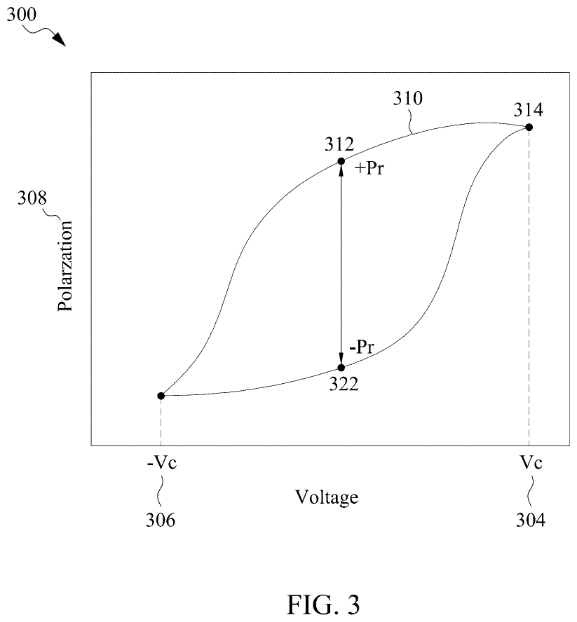

Referring to FIG. 3, depicted is such a PV curve (e.g., 300) associated with the ferroelectric films 226A-B, in accordance with some embodiments. The application of a coercive voltage (i.e., V_{C}) across electrodes of the ferroelectric film may result in polarization of the ferroelectric film. For example, the coercive voltage may be applied as a sweeping voltage across the corresponding WL structure (e.g., 224A-D) and corresponding BL/SL structures (e.g., 230 and 232). The voltage axis 302 may be centered around any voltage, but in some embodiments will be centered around 0 volts and FIG. 3 will be referred to thusly. Applying a positive voltage to the ferroelectric film (e.g., a positive voltage applied to the WL structure with the BL/SL structures tied to ground), such as V_{C} 304, may saturate the polarization of the device, illustrated by a saturation point 314 on the PV curve 300, such that additional voltage may not result in substantial additional polarization. Another voltage (e.g., a voltage twice the magnitude of V_{C}) may result in a breakdown of the dielectric properties of the ferroelectric film (i.e., sometimes referred to as a breakdown voltage (V_{BD})). In some embodiments, VBD may be very close to V_{C}. In some embodiments, the voltage of the saturation point 314 may exceed that of V_{BD}, wherein a V_{C} of lesser amplitude than the saturation voltage may be selected, in order to avoid breakdown of the ferroelectric film. In some embodiments where V_{BD} exceeds the saturation voltage, a V_{C} may be selected in excess of the magnitude of the voltage of the saturation point 314. Adjusting the applied V_{C} 304 upward (i.e., approaching or exceeding the saturation point 314), may ensure a complete polarization of the device (which may result in increased performance and/or reliability), and adjusting the amplitude of the applied V_{C} 304 downward (i.e., increasing a margin to V_{BD}) may increase device longevity (e.g., may avoid electro-migration failures).

Following the application of V_{C} 304 to the ferroelectric film (e.g., by applying the voltage to two electrodes disposed on opposite sides of the film), V_{C} may be removed from the ferroelectric film. For example, the circuit may be opened, and the charges disposed along the two electrodes may gradually leak to normalize the voltage, or the ferroelectric film may be grounded (i.e., a ground voltage may be applied thereto). Upon reaching a ground state, the PV curve 300 may relax to a polarization point 312 (i.e., along the upper surface 310 of the PV curve 300). The application of a lower or higher voltage may result in a somewhat lower or higher polarization. Thus, the application of a plurality of magnitudes of V_{C} may result in a plurality of respective positive polarization point 312 values along a polarization axis 308. A plurality of discrete bit values, or a continuous value (e.g., an analog value or an undefined value used to generate random numbers) may be stored on the ferroelectric film. In some embodiments, a voltage may be applied to the ferroelectric film for an insufficient time to complete polarization, and thus polarization may also be controlled.

Application of a negative V_{C} 306 may polarize the ferroelectric film to a negative polarization point 322 when in a relaxed (e.g., ground) state. In some embodiments, the negative polarization point 322 and positive polarization point 312 may correspond to a logical “1” and logical “0,” respectively. In some embodiments, the ferroelectric film may be symmetrical or substantially symmetrical, wherein the magnitude of V_{C} 304 and −V_{C} 306 may be equal or substantially equal, whereas in other embodiments, the magnitude of V_{C} 304 may be substantially higher or lower than the magnitude of −V_{C} 306. In some such embodiments, V_{C} may be applied directly to the ferroelectric film, and the difference in magnitude between V_{C} 304 and −V_{C} 306 may be due to intrinsic properties of the ferroelectric film. Alternatively or additionally, asymmetries between V_{C} 304 and −V_{C} 306 may be a result of additional circuit elements, such as a current sense resistors, capacitors, protection diodes, etc., which V_{C} 304/or and −V_{C} 306 may be applied to. Although V_{C} 304 and −V_{C} 306 may vary in amplitude and may comprise many values, V_{C} may be referred to generally herein, as to relate to any coercive voltage which may be intended to adjust the polarization of the ferroelectric film (e.g., a positive or negative value).

Advantageously, if there is any defect present in the ferroelectric films of the memory block 140, it can be identified through such an emulating PV curve (of the ferroelectric films 226A-B). For example, through the emulating PV curve, any defect (e.g., insufficient PV window) in a corresponding PV curve of the memory block 140 can be quickly identified. Further, by forming the memory cells in such a three-dimensional manner, a contact area between the WL structures and the ferroelectric films can be flexibly and significantly increased, which can monitor the PV curve more accurately. For example, by forming the WL structure with one or more crosses (i.e., adding one or more memory layers), the contact area between the WL structure and the corresponding ferroelectric film(s) can be (e.g., vertically) extended, which will be discussed in further detail with respect to FIG. 18.

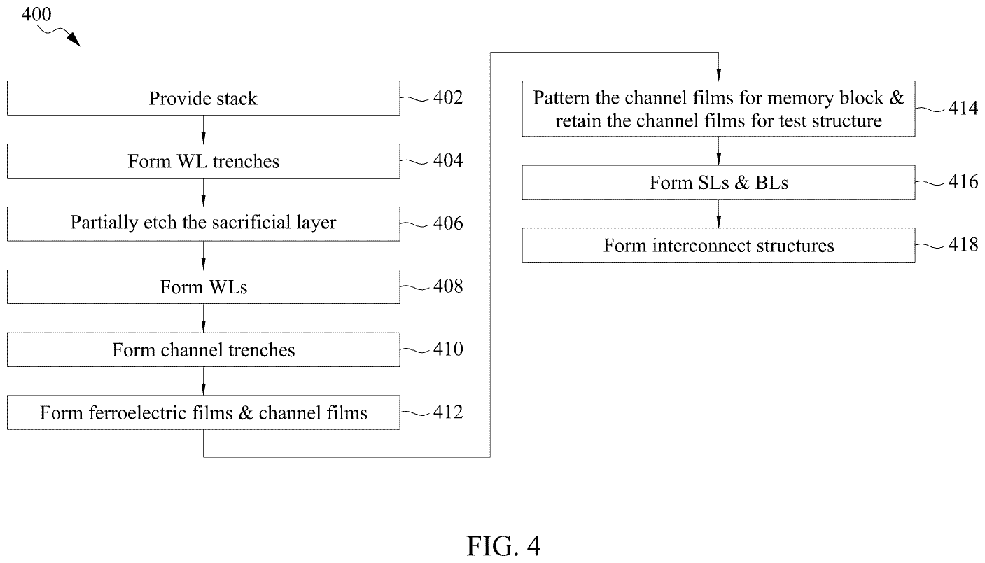

FIG. 4 illustrates a flowchart of a method 400 to form a memory device, according to various embodiments of the present disclosure. For example, at least some of the operations (or steps) of the method 400 can be performed to fabricate, make, or otherwise form a memory device having a memory structure and a corresponding test structure. The memory structure and test structure can be concurrently formed by performing the operations of the method 400, in accordance with various embodiments. Each of the memory structure and test structure includes a number of ferroelectric films, each of which is electrically coupled between a gate (e.g., implemented as a WL structure) and a channel film that is further coupled to a source (e.g., implemented as a SL structure) and a drain (e.g., implemented as a BL structure).

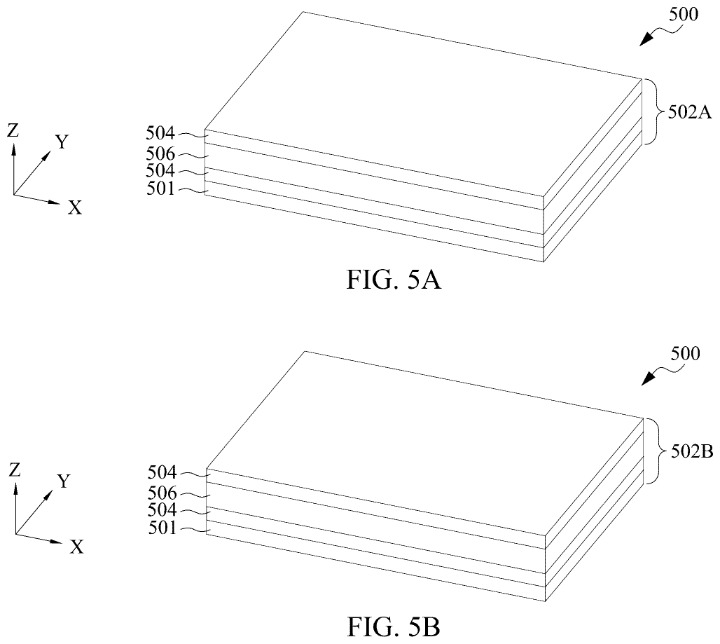

The method 400 is merely an example, and is not intended to limit the present disclosure. Accordingly, it should be understood that additional operations may be provided before, during, and after the method 400 of FIG. 4, and that some other operations may only be briefly described herein. In some embodiments, operations of the method 400 may be associated with perspective views of an example memory device 500 at various fabrication stages as shown in FIGS. 5A, 5B, 6A, 6B, 7A, 7B, 8A, 8B, 9A, 9B, 10A, 10B, 11A, 11B, 12A, 12B, 13A, and 13B, respectively. FIGS. 5A-13A may correspond to a first portion of the memory device 500 configured to form a test structure (e.g., 140A of FIG. 2), while FIGS. 5B-13B may correspond to a second portion of the memory device 500 configured to form a corresponding memory structure (e.g., 140 of FIG. 2) monitored by the test structure.

In brief overview, the method 4500 starts with operation 402 of providing a stack of one or more insulating layers and one or more sacrificial layers over a substrate. The method 400 continues to operation 404 of forming a number of WL trenches. The method 400 continues to operation 406 of partially etching the sacrificial layer(s) through the WL trenches. The method 400 continues to operation 408 of forming a number of WL structures. The method 400 continues to operation 410 of forming a number of channel trenches. The method 400 continues to operation 412 of forming a number of ferroelectric films and a number of channel films in the channel trenches. The method 400 continues to operation 414 of patterning the channel films for a memory structure and retaining the channel films for a test structure. The method 400 continues to operation 416 of forming a number of BL structures and SL structures. The method 400 continues to operation 418 of forming a number of interconnect structures.

Corresponding to operation 402 of FIG. 4, FIGS. 5A and 5B illustrate perspective views of the first portion and the second portion of the memory device 500 in which a stack 502A is formed over a substrate 501 and a stack 502B is formed over the substrate 501, respectively, at one of the various stages of fabrication, in accordance with various embodiments. The first portion and second portion may be formed on a first area and second area of the substrate 501, respectively. In the following discussions, the first portion and first area may be interchangeably used, and the second portion and second area may be interchangeably used. Operation 402 can be performed on the first portion and second portion concurrently, e.g., the stack 502A and stack 502B may be concurrently formed over the substrate 501.

The substrate 501 may be a semiconductor substrate, such as a bulk semiconductor, a semiconductor-on-insulator (SOI) substrate, or the like, which may be doped (e.g., with a p-type or an n-type dopant) or undoped. The substrate 501 may be a wafer, such as a silicon wafer. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 501 may include silicon; germanium; a compound semiconductor including silicon carbide, gallium arsenic, gallium phosphide, indium phosphide, indium arsenide, and/or indium antimonide; an alloy semiconductor including SiGe, GaAsP, AllnAs, AlGaAs, GainAs, GainP, and/or GainAsP; or combinations thereof. Other materials are within the scope of the present disclosure. For example, the substrate 501 may include an insulating material (e.g., silicon nitride (SiN)) that function as an etch stop layer disposed over a semiconductor substrate.

The stack 502A/B includes a number of insulating layers 504 and a number of sacrificial layers 506 alternately stacked on top of one another over the substrate 501 along a vertical direction (e.g., the Z direction). Although two insulating layers 504 and one sacrificial layer 506 are shown in the illustrated embodiments of FIGS. 5A-B, it should be understood that the stack 502A/B can include any number of insulating layers and any number of sacrificial layers alternately disposed on top of one another, while remaining within the scope of the present disclosure.

Although the stack 502A/B directly contacts the substrate 501 in the illustrated embodiment of FIGS. 5A-B (and the following figures), it should be understood that the stack 502A/B may be separated from a top surface of the substrate 501. For example, a number of (planar and/or non-planar) transistors may be formed over the substrate 501, and a number of metallization layers, each of which includes a number of contacts electrically connecting to those transistors, may be formed between the substrate 501 and the stack 502A/B. As used herein, the alternately stacked insulating layers 504 and sacrificial layers 506 may refer to each of the sacrificial layers 506 being adjoined by two adjacent insulating layers 504. The insulating layers 504 may have the same thickness thereamongst, or may have different thicknesses. The sacrificial layers 506 may have the same thickness thereamongst, or may have different thicknesses. The stack 502A/B may begin with the insulating layer 504 (as shown in FIGS. 5A-B) or the sacrificial layer 506 (in some other embodiments).

The insulating layers 504 can include at least one insulating material. The insulating materials that can be employed for the insulating layer 504 include, but are not limited to, silicon oxide (including doped or undoped silicate glass), silicon nitride, silicon oxynitride, organosilicate glass (OSG), spin-on dielectric materials, dielectric metal oxides that are generally known as high dielectric constant (high-k) dielectric oxides (e.g., aluminum oxide, hafnium oxide, etc.) and silicates thereof, dielectric metal oxynitrides and silicates thereof, and organic insulating materials. Other insulating materials are within the scope of the present disclosure. In one embodiment, the insulating layers 504 include silicon oxide.

The sacrificial layers 506 may include an insulating material, a semiconductor material, or a conductive material. The material of the sacrificial layers 506 is a sacrificial material that can be subsequently removed selective to the material of the insulating layers 504. In accordance with various embodiments, each sacrificial layer 506, sandwiched by a respective pair of insulating layers 504, may correspond to a memory layer (or level), in which a number of memory cells that are laterally disposed from one another can be formed. Non-limiting examples of the sacrificial layers 506 include silicon nitride, an amorphous semiconductor material (such as amorphous silicon), and a polycrystalline semiconductor material (such as polysilicon). In one embodiment, the sacrificial layers 506 can be spacer material layers that include silicon nitride or a semiconductor material including at least one of silicon or germanium. Other materials are within the scope of the present disclosure.

The stack 502A/B can be formed by alternately depositing the respective materials of the insulating layers 504 and sacrificial layers 506 over the substrate 501. In some embodiments, one of the insulating layers 504 can be deposited, for example, by chemical vapor deposition (CVD), followed by depositing such as, for example, using CVD or atomic layer deposition (ALD), one of the sacrificial layers 506. Other methods of forming the stack 502 are within the scope of the present disclosure.

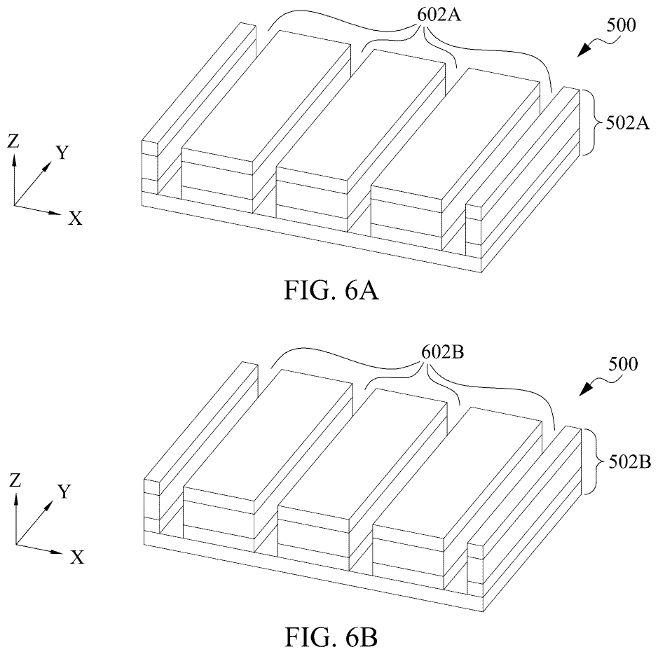

Corresponding to operation 404 of FIG. 4, FIGS. 6A and 6B illustrate perspective views of the first portion and the second portion of the memory device 500 in which a number of WL trenches 602A are formed and a number of WL trenches 602B are formed, respectively, at one of the various stages of fabrication, in accordance with various embodiments. Operation 404 can be performed on the first portion and second portion concurrently, e.g., the WL trenches 602A in the first portion and the WL trenches 602B in the second portion may be may be concurrently formed.

The WL trenches 602A/B are formed to extend along a same lateral direction (e.g., the Y direction) and spaced apart from one another along another lateral direction (e.g., the X direction), i.e., the WL trenches 602A/B are parallel with each other. The WL trenches 602A and 602B may be formed by at least an etching process to etch a number of portions of the stack 502A and 502B, respectively. The etching process for forming the WL trenches 602A/B may include a plasma etching process, which can have a certain amount of anisotropic characteristic. For example, the WL trenches 602A/B may be formed, for example, by depositing a photoresist or other masking layer on a top surface of the stack 502A/B, with a pattern corresponding to the WL trenches 602A/B defined in the masking layer (e.g., via photolithography, e-beam lithography, or any other suitable lithographic process). In other embodiments, a hard mask may be used.

Subsequently, the stack 502A/B may be etched using a plasma etching process (including radical plasma etching, remote plasma etching, and other suitable plasma etching processes, RIE, DRIE), gas sources such as Cl₂, HBr, CF₄, CHF₃, CH₂F₂, CH₃F, C₄F₆, BCl₃, SF₆, H₂, NF₃, and other suitable etch gas sources and combinations thereof can be used with passivation gases such as N₂, O₂, CO₂, SO₂, CO, CH₄, SiCl₄, and other suitable passivation gases and combinations thereof. Moreover, for the plasma etching process, the gas sources and/or the passivation gases can be diluted with gases such as Ar, He, Ne, and other suitable dilutive gases and combinations thereof to form the WL trenches 602A/B. As a non-limiting example, a source power of 10 Watts to 3,000 Watts, a bias power of 0 watts to 3,000 watts, a pressure of 1 millitorr to 5 torr, and an etch gas flow of 0 sccm to 5,000 sccm may be used in the etching process. However, it is noted that source powers, bias powers, pressures, and flow rates outside of these ranges are also contemplated. In various embodiments, the etching process used to form the WL trenches 602A/B etches through each of the sacrificial layer 506 and insulating layers 504 of the stack 502A/B such that each of the WL trenches 602A/B can extend form the topmost insulating layer 504 through the bottommost insulating layer 504 to the substrate 501, in the illustrated example of FIGS. 6A-B.

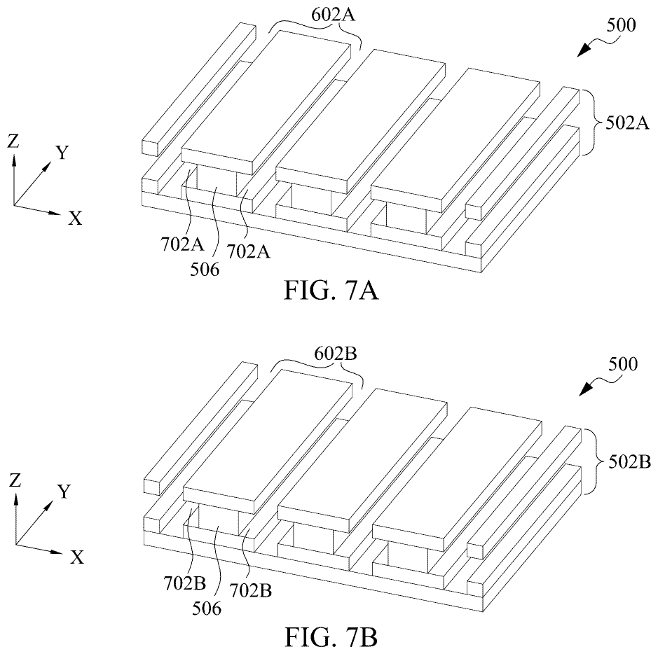

Corresponding to operation 406 of FIG. 4, FIGS. 7A and 7B illustrate perspective views of the first portion and the second portion of the memory device 500 in which the sacrificial layers (or segments) 506 of the stack 502A are partially etched and the sacrificial layers (or segments) 506 of the stack 502B are partially etched, respectively, at one of the various stages of fabrication, in accordance with various embodiments. Operation 406 can be performed on the first portion and second portion concurrently, e.g., the sacrificial layers 506 in the first portion and the sacrificial layers 506 in the second portion may be may be concurrently etched.

Surfaces (or sidewalls) of the sacrificial layer 506 exposed by the WL trenches 602A/B are partially etched so as to reduce a width (e.g., along the X direction) of the sacrificial layer 506 relative to the corresponding insulating layers 504 in the stack 502A/B. For example, the sacrificial layer 506 is partially etched from their exposed surfaces facing toward or away from the X direction (sometimes referred to as an etching back process), thereby reduces a width of each of the sacrificial layer 506 along the X direction. In some embodiments, the sacrificial layer 506 may be etched using a wet etch process (e.g., hydrofluoric etch, buffered hydrofluoric acid). In other embodiments, the exposed surfaces of the sacrificial layer 506 may be partially etched using a plasma etching process (including radical plasma etching, remote plasma etching, and other suitable plasma etching processes, RIE, DRIE), gas sources such as Cl₂, HBr, CF₄, CHF₃, CH₂F₂, CH₃F, C₄F₆, BCl₃, SF₆, H₂, NF₃, and other suitable etch gas sources and combinations thereof can be used with passivation gases such as N₂, O₂, CO₂, SO₂, CO, CH₄, SiCl₄, and other suitable passivation gases and combinations thereof. Moreover, for the plasma etching process, the gas sources and/or the passivation gases can be diluted with gases such as Ar, He, Ne, and other suitable dilutive gases and combinations thereof. As a non-limiting example, a source power of 10 Watts to 3,000 Watts, a bias power of 0 watts to 3,000 watts, a pressure of 1 millitorr to 5 torr, and an etch gas flow of 0 sccm to 5,000 sccm may be used in the etching process. However, it is noted that source powers, bias powers, pressures, and flow rates outside of these ranges are also contemplated.

Partially etching the sacrificial layer 506 in the X direction reduces a width of the sacrificial layer 506 relative to the insulating layers 504 disposed in the stack 502A/B such that a number of recesses 702A and a number of recesses 702B are formed in the stacks 502A and 502B, respectively. Boundaries of each of such recess 702A/B are formed by top and bottom surfaces of adjacent insulating layers 504 and a surface of the partially etched sacrificial layer 506 that face the corresponding WL trenches 602A/B. In various embodiments, the recess 702A/B each extend along a lateral direction (e.g., the Y direction).

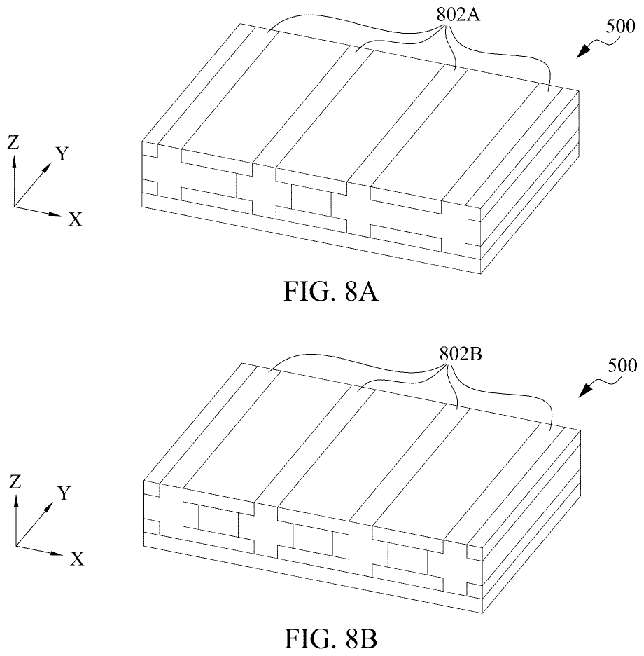

Corresponding to operation 408 of FIG. 4, FIGS. 8A and 8B illustrate perspective views of the first portion and the second portion of the memory device 500 in which a number of WL structures 802A are formed and a number of WL structures 802B are formed, respectively, at one of the various stages of fabrication, in accordance with various embodiments. Operation 408 can be performed on the first portion and second portion concurrently, e.g., the WL structures 802A in the first portion and the WL structures 802B in the second portion may be concurrently formed. The WL structures 802A may be an implementation of the WL structures 224A-D of FIG. 2, and the WL structures 802B may be an implementation of the WL structures 204A-D of FIG. 2, in various embodiments.

The WL structures 802A may be formed by filling the WL trenches 602A and the recesses 702A (FIG. 7A) with a metal material. Similarly, the WL structures 802B may be formed by filling the WL trenches 602B and the recesses 702B (FIG. 7A) with the same metal material. As such, the WL structures 802A/B each extend along a lateral direction (e.g., the Y direction). The metal material, used to form the WL structures 802A/B, may be selected from the group including aluminum, tungsten, tungsten nitride, copper, cobalt, silver, gold, chrome, ruthenium, platinum, titanium, titanium nitride, tantalum, tantalum nitride, nickel, hafnium, and combinations thereof. Other metal materials are within the scope of the present disclosure. The WL structures 802A/B can be formed by overlaying the workpiece with the above-listed metal material by, for example, chemical vapor deposition (CVD), physical vapor deposition (PVD), electroless plating, electroplating, or combinations thereof. Prior to forming the WL structures 802A/B, an adhesive layer may be conformally formed in the recesses 702A/B to enhance the adhesion between the materials of the sacrificial layer 506 and the WL structures 802A/B. Further, following the deposition process of the WL structures 802A/B, a polishing process may be performed to remove the excess metal material. Other methods of forming the WL structures 802A/B are within the scope of the present disclosure.

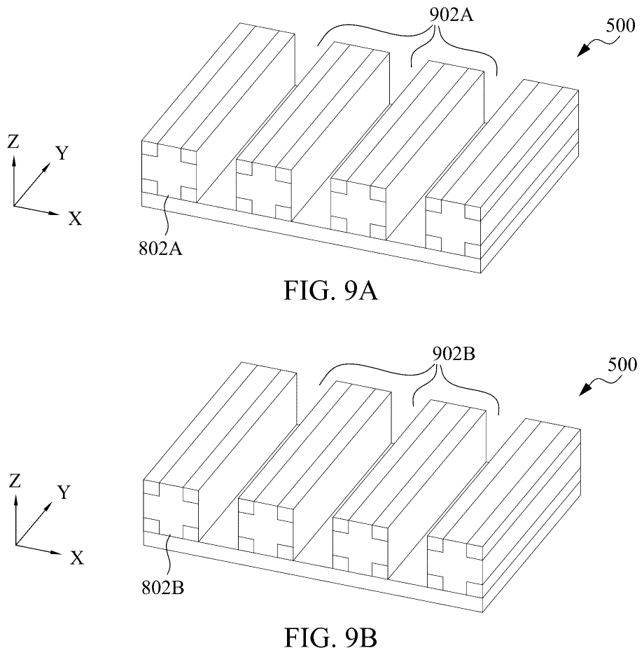

Corresponding to operation 410 of FIG. 4, FIGS. 9A and 9B illustrate perspective views of the first portion and the second portion of the memory device 500 in which a number of channel trenches 902A are formed and a number of channel trenches 902B are formed, respectively, at one of the various stages of fabrication, in accordance with various embodiments. Operation 410 can be performed on the first portion and second portion concurrently, e.g., the channel trenches 902A in the first portion and the channel trenches 902B in the second portion may be concurrently formed.

Following the formation of the WL structures 802A/B, an etching process for removing some of the remaining portions of the stack 502A/B can be performed to form the channel trenches 902A/B. For example, the etching process can remove the sacrificial layer 506, and the insulating layers 504 disposed thereon and therebelow, respectively. As such, each WL structure 802A/B can have a sidewall of its horizontal portion exposed by a corresponding channel trench 902A/902B. Specifically, the horizontal portion of each WL structure 802A/B can be sandwiched by two remaining portions of the insulating layers 504 at its respective ends. Further, the upper remaining portions of the insulating layers 504 can sandwich a vertical portion of the WL structure 802A/B, and the lower remaining portion of the insulating layers 504 can sandwich the vertical portion of the WL structure 802A/B. Alternatively stated, each WL structure 802A/B, with its cross-section present in a cross shape, is in contact with four remaining portion of the insulating layers 504 at its four corners.

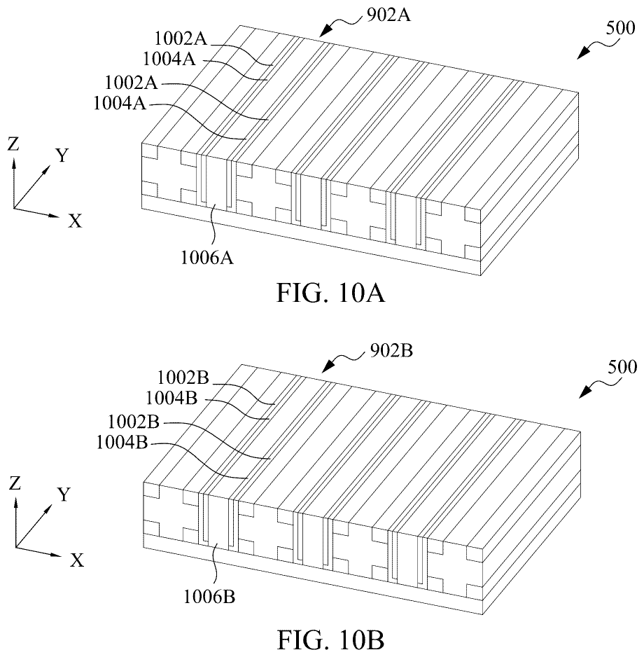

Corresponding to operation 412 of FIG. 4, FIGS. 10A and 10B illustrate perspective views of the first portion and the second portion of the memory device 500 in which a number of ferroelectric films 1002A and channel films 1004A are formed and a number of ferroelectric films 1002B and channel films 1004B are formed, respectively, at one of the various stages of fabrication, in accordance with various embodiments. Operation 412 can be performed on the first portion and second portion concurrently, e.g., the ferroelectric films 1002A and channel films 1004 in the first portion and the ferroelectric films 1002B and channel films 1004B in the second portion may be concurrently formed. The ferroelectric films 1002A may be an implementation of the ferroelectric films 226A/B of FIG. 2, the channel films 1004A may be an implementation of the channel films 228A/B of FIG. 2, and the ferroelectric films 1002B may be an implementation of the ferroelectric films 206A/B of FIG. 2, while the channel films 208A-F may not be formed yet at the current fabrication stage, in various embodiments.

The ferroelectric films 1002A/1002B and channel films 1004A/1004B shown in FIGS. 10A-B can be formed by performing at least some of the following processes: depositing a (e.g., conformal) ferroelectric material lining each of the channel trenches 902A/B (FIGS. 9A-B); depositing a (e.g., conformal) semiconductor material over a corresponding one of the ferroelectric material; etching respective lateral portions of the ferroelectric material and semiconductor material disposed at a bottom of each channel trench 902A/B; and depositing an insulating material to fill the remaining portion of each channel trench 902A/B.

In this way, a pair of the ferroelectric films 1002A/1002B can extend along (inner) sidewalls of each of the channel trenches 902A/B, respectively, and a pair of the channel films 1004A/1004B (formed of the semiconductor material) can extend along the corresponding pair of ferroelectric films 1002A/1002B, respectively. Alternatively stated, each of the ferroelectric films 1002A/1002B and channel films 1004A/1004B extend along the Z direction and further extend along the Y direction. Accordingly, each of the channel films 1004A/1004B is (e.g., electrically) coupled to a corresponding one of the WL structures 802A/B through a corresponding one of the ferroelectric films 1002A/1002B. Further, such a pair of the channel films 1004A/1004B can be isolated or spaced apart from each other, e.g., along the X direction, with an insulating layer 1006A/B that can be formed of the similar material to the insulating layers 504.

The foregoing ferroelectric material, used to form the ferroelectric films 1002A/B, includes, and/or consists essentially of, at least one ferroelectric material such as hafnium oxide (such as hafnium oxide containing at least one dopant selected from Al, Zr, and Si and having a ferroelectric non-centrosymmetric orthorhombic phase), zirconium oxide, hafnium-zirconium oxide, bismuth ferrite, barium titanate (such as BaTiO₃; BT), colemanite (such as Ca₂B₆O₁₁·5H₂O), bismuth titanate (such as Bi₄Ti₃O₁₂), europium barium titanate, ferroelectric polymer, germanium telluride, langbeinite (such as M₂M′₂(SO₄)₃ in which M is a monovalent metal and M′ is a divalent metal), lead scandium tantalate (such as Pb(ScₓTa₁₋ₓ)O₃), lead titanate (such as PbTiO₃; PT), lead zirconate titanate (such as Pb (Zr,Ti) O₃; PZT), lithium niobate (such as LiNbO₃; LN), (LaAlO₃)), polyvinylidene fluoride (CH₂CF₂)ₙ, potassium niobate (such as KNbO₃), potassium sodium tartrate (such as KNaC₄H₄O₆·4H₂O), potassium titanyl phosphate (such as KO₅PTi), sodium bismuth titanate (such as Na_{0.5}Bi_{0.5}TiO₃ or Bi_{0.5}Na_{0.5}TiO₃), lithium tantalate (such as LiTaO₃(LT)), lead lanthanum titanate (such as (Pb,La)TiO₃(PLT)), lead lanthanum zirconate titanate (such as (Pb,La)(Zr,Ti)O₃ (PLZT)), ammonium dihydrogen phosphate (such as NH₄H₂PO₄(ADP)), or potassium dihydrogen phosphate (such as KH₂PO₄(KDP)).

The foregoing semiconductor material, used to form the channel films 1004A/B, may include a doped or undoped semiconductor material such as, for example, Si (e.g., polysilicon or amorphous silicon), Ge, SiGe, silicon carbide (SiC), indium gallium zinc oxide (IGZO), indium tin oxide (ITO), indium zinc oxide (IZO), indium tungsten oxide (IWO), or combinations thereof. The semiconductor material can be deposited (as a blanket layer) over the workpiece as a continuous liner structure, for example, by a conformal deposition method such as atomic layer deposition (ALD) or chemical vapor deposition (CVD). Other deposition methods are within the scope of the present disclosure.

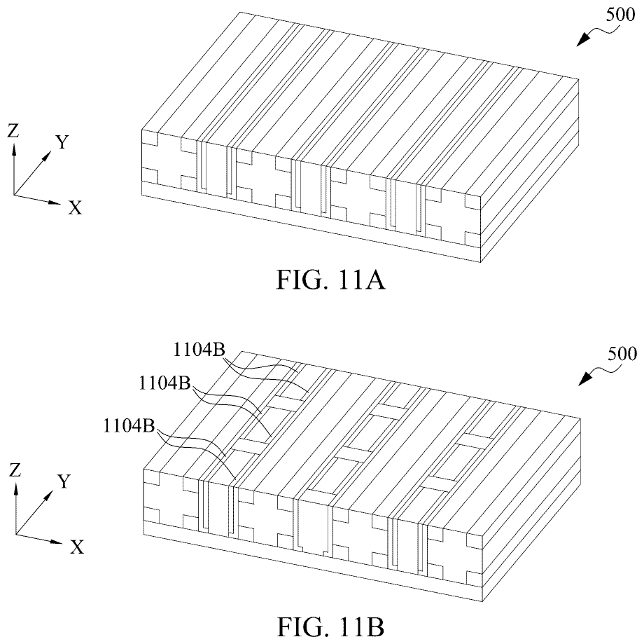

Corresponding to operation 414 of FIG. 4, FIGS. 11A and 11B illustrate perspective views of the first portion and the second portion of the memory device 500 in which the channel films 1004A are retained and the channel films 1004B are pattern to form channel films 1104B, respectively, at one of the various stages of fabrication, in accordance with various embodiments. Operation 414 can be performed only on the second portion, while the first portion may be covered by a mask layer 1102. The channel films 1104B may be an implementation of the channel films 208A-F of FIG. 2, in various embodiments.

The channel films 1104B are formed by dividing, cutting, or otherwise patterning each of the continuously extending channel films 1004A/B into a respective number of discrete portions. These “cut” discrete portions (i.e., the channel films 1104B) are spaced apart from each other along the Y direction, as shown. In various embodiments, the channel films 1104B may be formed by performing at least some of the following processes: forming a patterned mask layer over the stack 502B that at least exposes respective portions of the channel films 1004A/B to be removed; using the mask layer to perform at least one etching process to remove the exposed portions; refilling the removed portions with an insulating material; and polishing the workpiece. It should be noted that during the formation process of channel films 1104B, the first portion of the memory device 500 remains fully covered by the mask layer 1102, as shown in FIG. 11A.

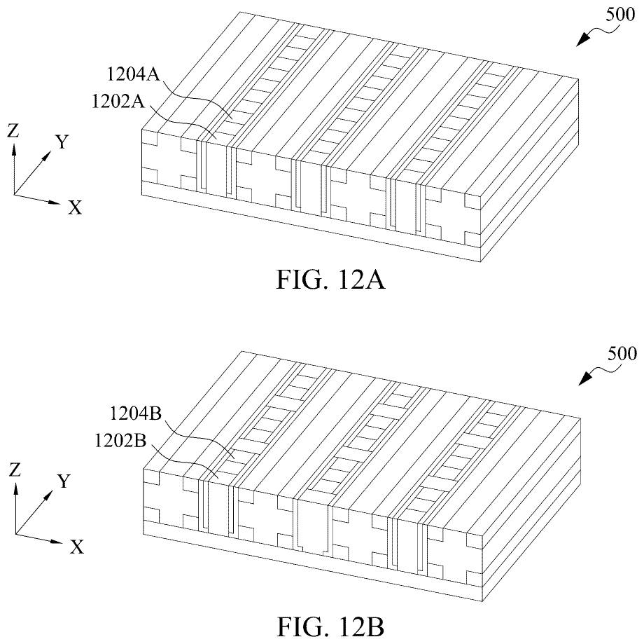

Corresponding to operation 416 of FIG. 4, FIGS. 12A and 12B illustrate perspective views of the first portion and the second portion of the memory device 500 in which a number of BL structures 1202A and SL structures 1204A are formed and a number of BL structures 1202B and SL structures 1204B are formed, respectively, at one of the various stages of fabrication, in accordance with various embodiments. Operation 416 can be performed on the first portion and second portion concurrently, e.g., the BL structures 1202A and SL structures 1204A in the first portion and the BL structures 1202B and SL structures 1204B in the second portion may be concurrently formed. The BL structure 1202A and SL structure 1204A may be an implementation of the BL structure 230 and SL structure 232 of FIG. 2, respectively, and the BL structure 1202B and SL structure 1204B may be an implementation of the BL structure 210 and SL structure 212 of FIG. 2, respectively.

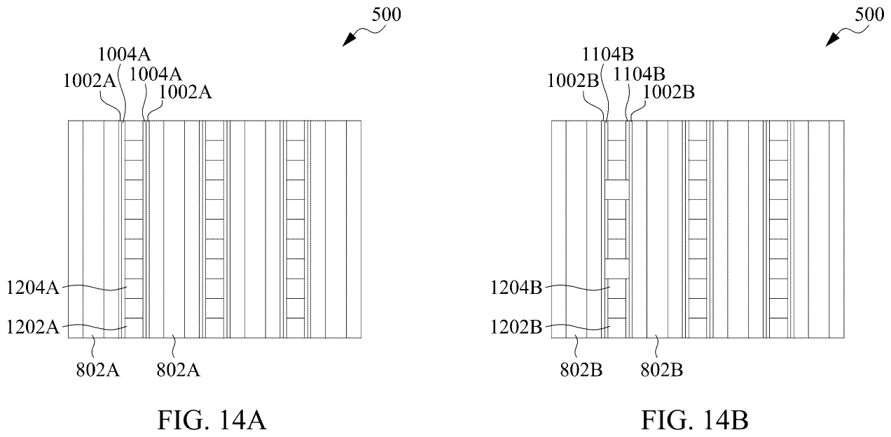

The BL structures 1202A/1202B and SL structures 1204A/1204B are formed to extend along the Z direction through the stack 502A/502B. In the first portion (e.g., FIG. 12A), each pair of the BL structures 1202A and SL structures 1204A are disposed next to (or coupled to) a pair of the channel films 1004A that face each other. In the second portion (e.g., FIG. 12B), each pair of the BL structures 1202B and SL structures 1204B are disposed next to (or coupled to) respective ends (e.g., along the Y direction) of a pair of the channel films 1104B that face each other. As such, a number of pairs of the BL structures 1202A and SL structures 1204A can be interposed between a corresponding pair of the channel films 1004A and a single pair of the BL structure 1202B and SL structure 1204B can be interposed between a corresponding pair of the patterned channel films 1104B, as shown in the illustrated embodiments of FIG. 12A and FIG. 12B, respectively. The arrangements of these features in the first portion and second portion may be better appreciated in top views of the memory device 500 shown in FIG. 14A and FIG. 14B, respectively. The BL structures 1202A/1202B and SL structures 1204A/1204B are each formed of a metal material. Example metal materials may be selected from the group including aluminum, tungsten, tungsten nitride, copper, cobalt, silver, gold, chrome, ruthenium, platinum, titanium, titanium nitride, tantalum, tantalum nitride, nickel, hafnium, and combinations thereof.

The BL structures 1202A/1202B and SL structures 1204A/1204B may be formed by performing at least some of the following processes: forming a patterned mask layer over the stack 502A/502B that at least exposes respective end portions of the insulating layers 1006A/1006B interposed between the facing pair of channel films 1004A/1402B; using the mask layer to perform at least one etching process to remove the exposed portions thereby forming a number of vertical recesses; (e.g., conformally) depositing one of the foregoing metal materials in the vertical recesses to form the BL structures 1202A/1202B and SL structures 1204A/1204B; and polishing the workpiece.

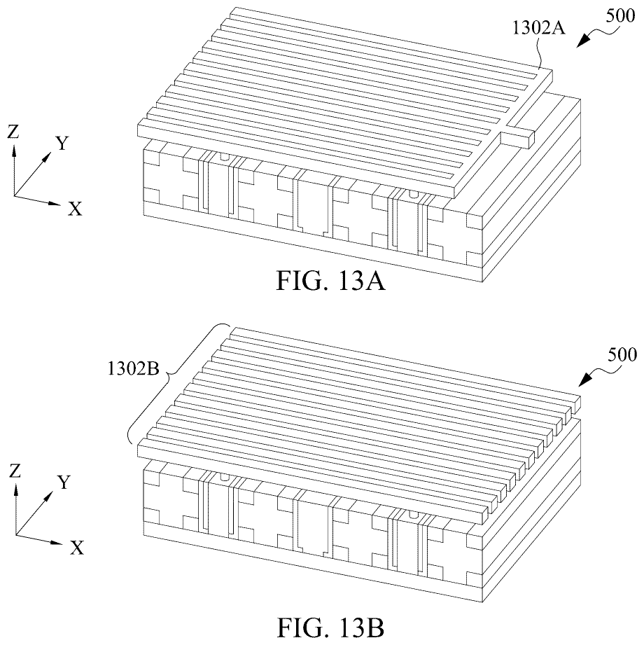

Corresponding to operation 418 of FIG. 4, FIGS. 13A and 13B illustrate perspective views of the first portion and the second portion of the memory device 500 in which an interconnect structure 1302A is formed and a number of interconnect structures 1302B are formed, respectively, at one of the various stages of fabrication, in accordance with various embodiments. Operation 418 can be performed on the first portion and second portion concurrently, the interconnect structure 1302A in the first portion and the interconnect structures 1302B in the second portion may be concurrently formed.

In the first portion (FIG. 13A), the interconnect structure 1302A may be formed to electrically couple all the BL structures 1202A and SL structures 1204A to each other. Each of the BL structures 1202A and SL structures 1204A is coupled to the interconnect structure 1302A through a respective via structure. Accordingly, the interconnect structure 1302A may have a number of portions extending in parallel along the X direction, and at least one portion extending along the Y direction connecting all such parallel portions, as shown in FIG. 13A. In the second portion (FIG. 13B), the interconnect structures 1302B, extending in parallel along the X direction, may each be formed to electrically couple a respective subset of the BL structures 1202B or SL structures 1204B. The interconnect structure 1302A and interconnect structures 1302B are each formed of a metal material. Example metal materials may be selected from the group including aluminum, tungsten, tungsten nitride, copper, cobalt, silver, gold, chrome, ruthenium, platinum, titanium, titanium nitride, tantalum, tantalum nitride, nickel, hafnium, and combinations thereof.

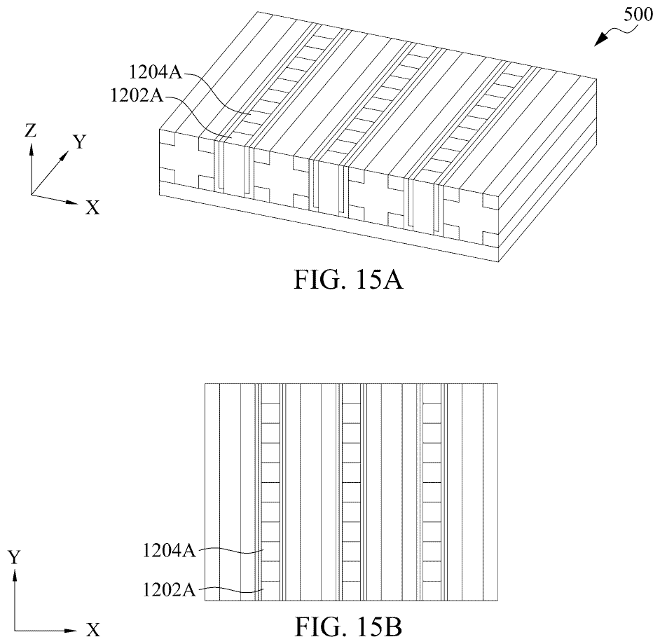

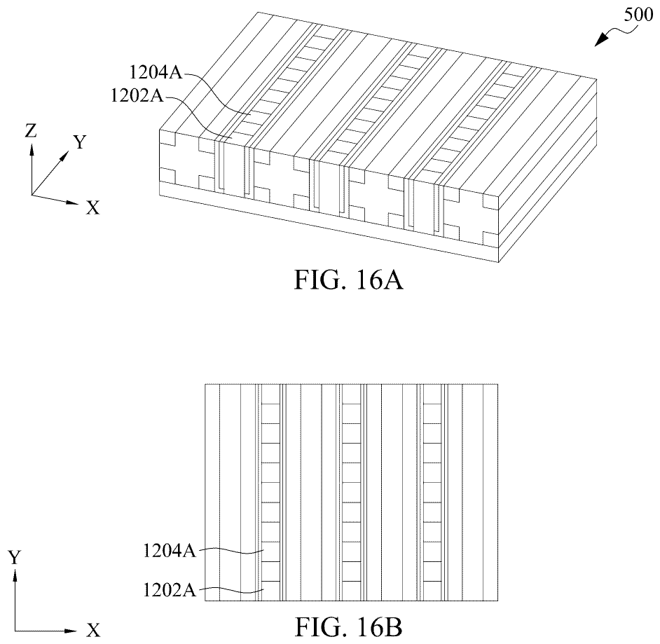

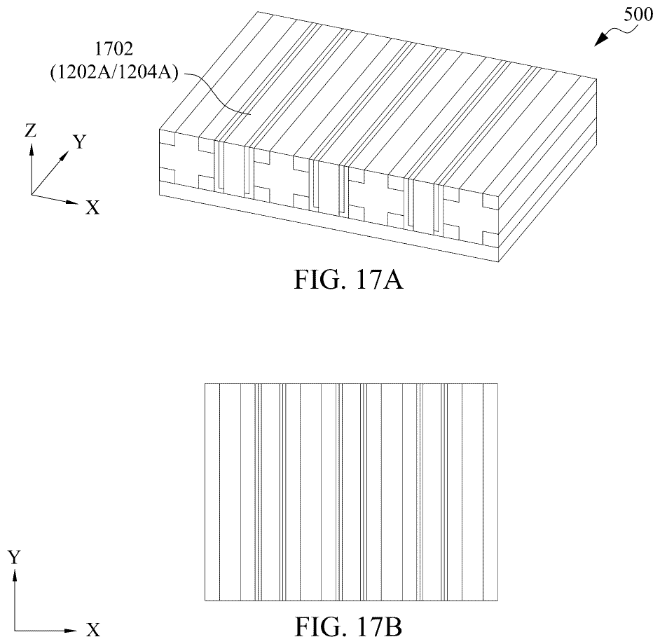

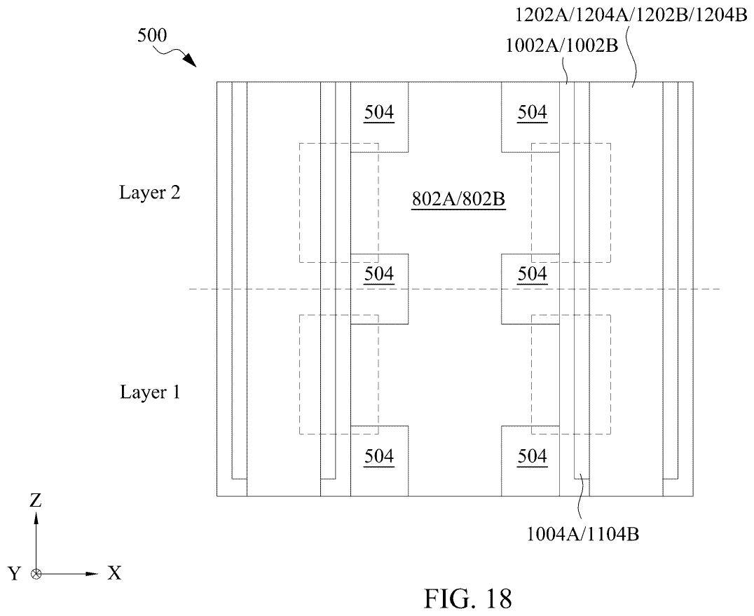

In some other embodiments, in the first portion, the BL structures 1202A and SL structures 1204A can be arranged in any of various other manners. As a comparison, the arrangement of BL structures 1202A and SL structures 1204A shown above are reproduced in the perspective view of FIG. 15A and the top view of FIG. 15B, respectively. In such an embodiment, the pairs of BL structures 1202A and SL structures 1204A in different columns extending along the Y direction may be staggered. Specifically, the BL structures 1202A and SL structures 1204A in any of the columns are laterally shifted (along the Y direction) from the BL structures 1202A and SL structures 1204A in a neighboring column. In another embodiment, the BL structures 1202A and SL structures 1204A in different columns may be aligned with each other (along the X direction), as shown in the perspective view of FIG. 16A and the top view of FIG. 16B, respectively. In yet another embodiment, the BL structures 1202A and SL structures 1204A in a single column may be coupled to one another thereby forming a merged BL/SL structure 1702, as shown in the perspective view of FIG. 17A and the top view of FIG. 17B, respectively.

As mentioned above, the memory device 500 can include more than one memory layer. FIG. 18 illustrates a cross-sectional vied of the memory device 500 that includes such an embodiment, for example, two memory layers, “Layer 1” and “Layer 2.” To form the memory device 500 in such a multi-layer structure, in operation 402 of the method 400, the stack 502A/B may be formed to have more than one sacrificial layers 506 alternately stacked with a corresponding number of insulating layers 504. For example, to form the two-layer memory device shown in FIG. 18, two sacrificial layers 506 and three insulating layers 504, alternately stacked on top of one another, may be formed as the initial stack 502A/B, followed by performing the remaining operations of the method 400.

As shown, the WL structure 802A/B can further extend along the Z direction to have one more cross, and thus, there may be six insulating layers 504 (each of which extends along the Y direction) coupled to the WL structure 802A/802B. Two vertically adjacent ones of the insulating layers 504 can define a corresponding memory layer. For example in FIG. 18, the bottommost insulating layers 504 and the middle insulating layers 504 can define Layer 1, and the middle insulating layers 504 and the topmost insulating layers 504 can define Layer 2. The WL structure 802A/B can be coupled to different (e.g., vertical) portions of the channel film 1004A/1104B (as enclosed by dotted boxes in FIG. 18) through respective portions of the ferroelectric film 1002A/1002B.

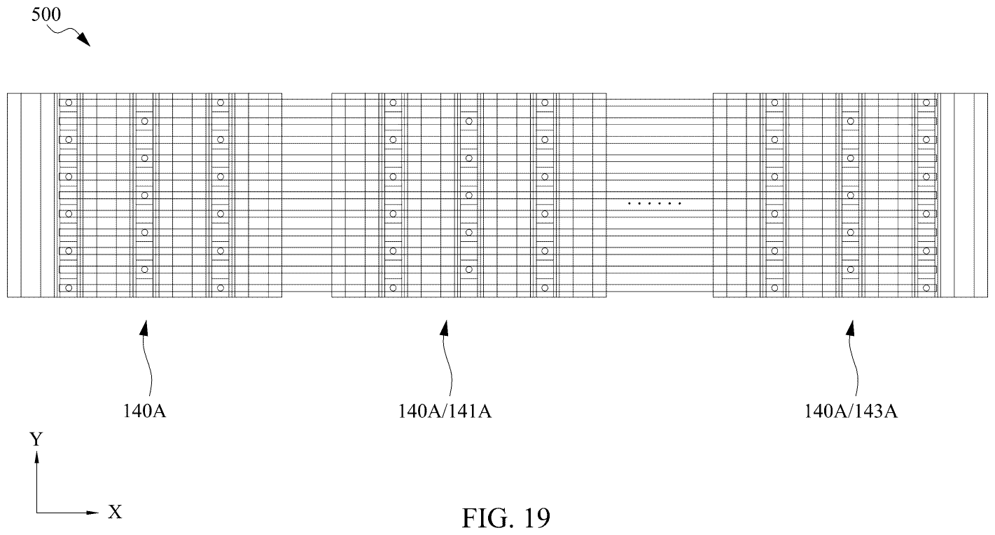

FIG. 19 illustrates a top view of the memory device 500 that includes more than one test structures 140A, corresponding to one memory structure, that are connected in parallel in some embodiments, or a number of test structures 140A, 141A, 143A, etc., corresponding to respectively different memory structures, that are connected in parallel in some other embodiments. As shown, the test structures 140A or 140A to 143A may be laterally arranged next to each other (along the X direction), with their BL structures and SL structures all electrically coupled to one another.

In one aspect of the present disclosure, a semiconductor device is disclosed. The semiconductor device includes a memory structure comprising a plurality of first memory cells. The semiconductor device includes a test structure disposed next to the memory structure and comprising a first monitor pattern. The plurality of first memory cells, arranged along a first lateral direction, that have a plurality of first channel films extending along a vertical direction, respectively, and share a first ferroelectric film extending along the vertical direction and the first lateral direction. The first monitor pattern includes: (a) a second channel film extending along the vertical direction and the first lateral direction; and (b) a second ferroelectric film extending along the vertical direction and the first lateral direction.

In another aspect of the present disclosure, a semiconductor device is disclosed. The semiconductor device includes a first word line (WL) structure extending along a first lateral direction. The semiconductor device includes a first ferroelectric film extending along the first lateral direction and along a vertical direction, and in physical contact with the first WL structure. The semiconductor device includes a plurality of first channel films separated from one another along the first lateral direction, extending along the vertical direction, and in physical contact with the first ferroelectric film. The semiconductor device includes a second WL structure extending along the first lateral direction. The semiconductor device includes a second ferroelectric film extending along the first lateral direction and along the vertical direction, and in physical contact with the second WL structure. The semiconductor device includes a single second channel film extending along the first lateral direction and along the vertical direction, and in physical contact with the second ferroelectric film.

In yet another aspect of the present disclosure, a method for fabricating memory devices is disclosed. The method includes forming, in a first area of a substrate, a first word line (WL) structure extending along a first lateral direction. The method includes forming, in a second area of the substrate, a second WL structure extending along the first lateral direction. The method includes forming, in the first area, a first ferroelectric film extending along the first lateral direction and along a vertical direction, and in physical contact with the first WL structure. The method includes forming, in the second area, a second ferroelectric film extending along the first lateral direction and along the vertical direction, and in physical contact with the second WL structure. The method includes forming, in the first area, a plurality of first channel films separated from one another along the first lateral direction, extending along the vertical direction, and in physical contact with the first ferroelectric film. The method includes forming, in the second area, a single second channel film extending along the first lateral direction and along the vertical direction, and in physical contact with the second ferroelectric film.

As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a first word line (WL) structure extending along a first lateral direction;
a first ferroelectric film extending along the first lateral direction and along a vertical direction, and in physical contact with the first WL structure;
a plurality of first channel films separated from one another along the first lateral direction, extending along the vertical direction, and in physical contact with the first ferroelectric film;
a second WL structure extending along the first lateral direction;
a second ferroelectric film extending along the first lateral direction and along the vertical direction, and in physical contact with the second WL structure; and
a second channel film extending along the first lateral direction and along the vertical direction, and in physical contact with the second ferroelectric film.

2. The semiconductor device of claim 1, further comprising:
a plurality of pairs of a first bit line (BL) structure and a first source line (SL) structure that are in physical contact with a corresponding one of the plurality of first channel films, each first BL structure and each first SL structure extending along the vertical direction; and
a plurality of pairs of a second BL structure and a second SL structure that are in physical contact with the second channel film, each second BL structure and each second SL structure extending along the vertical direction.

3. The semiconductor device of claim 2, further comprising a pair of first interconnect structures electrically coupled to a corresponding one of the plurality of pairs of the first BL structure and the first SL structure, respectively.

4. The semiconductor device of claim 3, further comprising a second interconnect structure electrically coupling the plurality of pairs of the second BL structure and the second SL structure to one another.

5. The semiconductor device of claim 4, wherein the second interconnect structure is connected to ground and the second WL structure is connected to a sweeping voltage to monitor a polarization-voltage curve associated with the second ferroelectric film.

6. The semiconductor device of claim 5, wherein the polarization-voltage curve associated with the second ferroelectric film is configured to emulate a polarization-voltage curve associated with the first ferroelectric film.

7. The semiconductor device of claim 1, further comprising a merged BL/SL structure that is in physical contact with the second channel film, the merged BL/SL structure extending along the vertical direction and the first lateral direction.

8. A method for manufacturing a memory device, comprising:
forming, in a first area of a substrate, a first word line (WL) structure extending along a first lateral direction;
forming, in a second area of the substrate, a second WL structure extending along the first lateral direction;
forming, in the first area, a first ferroelectric film extending along the first lateral direction and along a vertical direction, and in physical contact with the first WL structure;
forming, in the second area, a second ferroelectric film extending along the first lateral direction and along the vertical direction, and in physical contact with the second WL structure;
forming, in the first area, a plurality of first channel films separated from one another along the first lateral direction, extending along the vertical direction, and in physical contact with the first ferroelectric film; and
forming, in the second area, a second channel film extending along the first lateral direction and along the vertical direction, and in physical contact with the second ferroelectric film.

9. The method of claim 8, wherein the forming the first word line (WL) structure and the forming the second WL structure are concurrently performed, and the forming the first ferroelectric film and the forming the second ferroelectric film are concurrently performed.

10. The method of claim 8, further comprising:
forming, in the first area, a plurality of pairs of a first bit line (BL) structure and a first source line (SL) structure that are in physical contact with a corresponding one of the plurality of first channel films, each first BL structure and each first SL structure extending along the vertical direction;
forming, in the second area, a plurality of pairs of a second BL structure and a second SL structure that are in physical contact with the second channel film, each second BL structure and each second SL structure extending along the vertical direction; and
forming, in the second area, an interconnect structure to electrically connect the plurality of pairs of the second BL structure and the second SL structure to one another.

11. The method of claim 10, wherein the interconnect structure is connected to ground.

12. The method of claim 9, wherein the second WL structure is connected to a sweeping voltage to monitor a polarization-voltage curve associated with the second ferroelectric film.

13. The method of claim 12, wherein the polarization-voltage curve associated with the second ferroelectric film is configured to emulate a polarization-voltage curve associated with the first ferroelectric film.

14. A semiconductor device, comprising:
a first word line (WL) structure extending along a first lateral direction;
a first ferroelectric film extending along the first lateral direction and along a vertical direction, and in physical contact with the first WL structure;
a plurality of first channel films separated from one another along the first lateral direction, extending along the vertical direction, and in physical contact with the first ferroelectric film;
a plurality of pairs of a first bit line (BL) structure and a first source line (SL) structure that are in physical contact with a corresponding one of the plurality of first channel films, each first BL structure and each first SL structure extending along the vertical direction; and
a plurality of pairs of a second BL structure and a second SL structure, each second BL structure and each second SL structure extending along the vertical direction.

15. The semiconductor device of claim 14, further comprising:
a second WL structure extending along the first lateral direction;
a second ferroelectric film extending along the first lateral direction and along the vertical direction, and in physical contact with the second WL structure; and
a second channel film extending along the first lateral direction and along the vertical direction, and in physical contact with the second ferroelectric film, wherein the plurality of pairs of the second BL structure and the second SL structure are in physical contact with the second channel film.

16. The semiconductor device of claim 14, further comprising a pair of first interconnect structures electrically coupled to a corresponding one of the plurality of pairs of the first BL structure and the first SL structure, respectively.

17. The semiconductor device of claim 15, further comprising a second interconnect structure electrically coupling the plurality of pairs of the second BL structure and the second SL structure to one another.

18. The semiconductor device of claim 17, wherein the second interconnect structure is connected to ground and the second WL structure is connected to a sweeping voltage to monitor a polarization-voltage curve associated with the second ferroelectric film.

19. The semiconductor device of claim 18, wherein the polarization-voltage curve associated with the second ferroelectric film is configured to emulate a polarization-voltage curve associated with the first ferroelectric film.

20. The semiconductor device of claim 15, further comprising a merged BL/SL structure that is in physical contact with the second channel film, the merged BL/SL structure extending along the vertical direction and the first lateral direction.
